(19) United States
(12) Patent Application Publication
(10) Pub. No.: US 2020/0185560 A1
(43) Pub. Date: Jun. 11, 2020

(54) SPAD-TYPE PHOTODIODE

(71) Applicant: Commissariat à l'Énergie Atomique et aux Énergies Alternatives, Paris (FR)

(72) Inventors: Cédric Giroud-Garampon, Grenoble Cedex 9 (FR); Norbert Moussy, Sainte Agnes (FR); Olivier Saxod, Grenoble Cedex 9 (FR)

(73) Assignee: Commissariat à l'Énergie Atomique et aux Énergies Alternatives, Paris (FR)

(21) Appl. No.: 16/704,906

(22) Filed: Dec. 5, 2019

(30) Foreign Application Priority Data
Dec. 7, 2018 (FR) 1872508

(51) Int. Cl. H01L 31/107; H01L 31/18

(52) U.S. Cl. CPC H01L 31/107; H01L 31/1804

(57) ABSTRACT

A SPAD-type photodiode including, in an upper portion of a semiconductor substrate of a first conductivity type, an alternation of vertically stacked regions of the first conductivity type and regions of a second conductivity type, the regions of the first conductivity type being in contact with a same first semiconductor via of the first conductivity type and the regions of the second conductivity type being in contact with a same second semiconductor via of the second conductivity type.

### CROSS-REFERENCE TO RELATED APPLICATIONS

This Application claims priority to French Patent Application No. 1872508, filed Dec. 7, 2018, the contents of which is incorporated herein by reference in its entirety.

### TECHNICAL BACKGROUND

The present application concerns the field of avalanche photodiodes for the detection of single photons, also called SPAD “Single Photon Avalanche Diode”) photodiodes.

### PRIOR ART

A SPAD photodiode is essentially formed by a PN junction reverse biased at a voltage greater than its avalanche threshold. When no electric charge is present in the depletion area or space charge area of the PN junction, the photodiode is in a non-conductive pseudo-steady state. When a photogenerated electric charge is injected into the depletion area, if the displacement speed of this charge in the depletion area is sufficiently high, that is, if the electric field in the depletion area is sufficiently intense, the photodiode is capable of avalanching. A single photon is thus capable of generating a measurable electric signal, and this, with a very short response time. SPAD photodiodes enable to detect radiations of very low intensity, and are in particular used for single photon detection and photon counting.

It would be desirable to at least partly improve certain aspects of known SPAD photodiodes.

### SUMMARY

Thus, an embodiment provides a SPAD-type photodiode comprising, in an upper portion of a semiconductor substrate of a first conductivity type, an alternation of vertically stacked regions of the first conductivity type and regions of a second conductivity type, the regions of the first conductivity type being in contact with a same first semiconductor via of the first conductivity type and the regions of the second conductivity type being in contact with a same second semiconductor via of the second conductivity type.

According to an embodiment, the alternation of regions of the first conductivity type and of regions of the second conductivity type forms a vertical stack of a plurality of PN junctions, each defining an avalanche area of the photodiode.

According to an embodiment, the PN junctions all substantially have the same avalanche voltage.

According to an embodiment, the regions of the first conductivity type have a doping level greater than that of the substrate.

According to an embodiment, in a first portion of a peripheral region of the photodiode, the regions of the first conductivity type extend laterally beyond the regions of the second conductivity type and, in a second portion of the peripheral region of the photodiode, the regions of the second conductivity type extend laterally beyond the regions of the first conductivity type, the first semiconductor via being arranged in the first portion of the peripheral region of the photodiode and the second semiconductor via being arranged in the second portion of the peripheral region of the photodiode.

According to an embodiment, except for the end regions of said alternation, each region of the first conductivity type is in contact, by its lower surface, with one of the regions of the second conductivity type and, by its upper surface, with another one of the regions of the second conductivity type, and each region of the second conductivity type is in contact, by its lower surface, with one of the regions of the first conductivity type and, by its upper surface, with another one of the regions of the first conductivity type.

According to an embodiment, the regions of the first conductivity type and the regions of the second conductivity type have substantially the same thickness.

According to an embodiment, the regions of the first conductivity type have a thickness greater than the thickness of the regions of the second conductivity type.

According to an embodiment, each region of the first conductivity type is in contact with a single region of the second conductivity type.

According to an embodiment, each region of the second conductivity type is in contact, by its lower surface, with one of the regions of the first conductivity type and, by its upper surface, with another one of the regions of the first conductivity type.

According to an embodiment:
at least one of the regions of the second conductivity type is in contact, by its lower surface, with one of the regions of the first conductivity type and, by its upper surface, with another one of the regions of the first conductivity type; and
at least another one of the regions of the second conductivity type is in contact with a single one of the regions of the first conductivity type.

According to an embodiment, the first and second conductivity types respectively are type P and type N.

Another embodiment provides a method of manufacturing a SPAD-type photodiode such as defined hereabove, wherein the substrate is formed by a sequence of successive epitaxy steps.

According to an embodiment, any two successive steps of the sequence of successive epitaxy steps are separated by at least one step of local implantation of dopant elements for the forming of at least one of the regions of the first or second conductivity type.

According to an embodiment, the method comprises no anneal of activation of the dopant elements between two successive steps of the sequence of epitaxy steps, the method comprising a single anneal of activation of the dopant elements common to all the regions of the first and second conductivity types at the end of the sequence of successive epitaxy steps.

### BRIEF DESCRIPTION OF THE DRAWINGS

The foregoing and other features and advantages will be discussed in detail in the following non-limiting description of specific embodiments in connection with the accompanying drawings, in which:

FIG. 1 is a partial simplified cross-section view of an example of a SPAD photodiode according to an embodiment;

FIG. 2 is a partial simplified top view of the SPAD photodiode of FIG. 1;

FIG. 3 is a partial simplified cross-section view illustrating a step of an example of a method of manufacturing the SPAD photodiode of FIG. 1;

FIG. 4 is a partial simplified cross-section view illustrating another step of an example of a method of manufacturing the SPAD photodiode of FIG. 1;

FIG. 5 is a partial simplified cross-section view illustrating another step of an example of a method of manufacturing the SPAD photodiode of FIG. 1;

FIG. 6 is a partial simplified cross-section view illustrating another step of an example of a method of manufacturing the SPAD photodiode of FIG. 1;

FIG. 7 is a partial simplified cross-section view illustrating another step of an example of a method of manufacturing the SPAD photodiode of FIG. 1;

FIG. 8 is a partial simplified cross-section view illustrating another step of an example of a method of manufacturing the SPAD photodiode of FIG. 1;

FIG. 9 is a partial simplified cross-section view of another example of a SPAD photodiode according to an embodiment;

FIG. 10 is a partial simplified cross-section view of another example of a SPAD photodiode according to an embodiment; and

FIG. 11 is a partial simplified cross-section view of another example of a SPAD photodiode according to an embodiment.

### DESCRIPTION OF THE EMBODIMENTS

The same elements have been designated with the same reference numerals in the different drawings. In particular, the structural and/or functional elements common to the different embodiments may be designated with the same reference numerals and may have identical structural, dimensional, and material properties.

For clarity, only those steps and elements which are useful to the understanding of the described embodiments have been shown and are detailed. In particular, a SPAD-type photodiode generally comprises secondary circuits, particularly a circuit for biasing its PN junction to a voltage greater than its avalanche threshold, a readout circuit capable of detecting that an avalanche of the photodiode has been triggered, as well as a quenching circuit having the function of interrupting the avalanche of the photodiode once the latter has been triggered. Such secondary circuits have not been shown in the drawings and will not be detailed, the described embodiments being compatible with the secondary circuits equipping known SPAD photodiodes.

Throughout the present disclosure, the term “connected” is used to designate a direct electrical connection between circuit elements with no intermediate elements other than conductors, whereas the term “coupled” is used to designate an electrical connection between circuit elements that may be direct, or may be via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, “lateral”, etc., or to terms qualifying directions, such as terms “horizontal”, “vertical”, etc., unless otherwise specified, it is referred to the orientation of the drawings, it being understood that, in practice, the described devices may be oriented differently.

The terms “about”, “approximately”, “substantially”, and “in the order of” are used herein to designate a tolerance of plus or minus 10%, preferably of plus or minus 5%, of the value in question.

A problem which is posed in known SPADs is that of the collection of the charges photogenerated in depth in the substrate, at a distance remote from the avalanche area of the photodiode, that is, the portion of the photodiode depletion area where the electric field is sufficiently intense for the avalanche to be triggered by a single charge. Indeed, beyond a certain distance from the PN junction, the electric field resulting from the reverse biasing of the PN junction becomes zero or is strongly attenuated, and no longer enables to drive the photogenerated charges towards the avalanche area. Only the random diffusion in the substrate is then capable of driving the photogenerated charges towards the avalanche area, with a non-negligible probability for the photogenerated charges never to reach the avalanche area or to reach it with a significant delay. This problem especially arises when charges photogenerated under the effect of a luminous radiation of high wavelength, for example, a radiation having a wavelength in the range from 750 to 1,200 nm in silicon, are desired to be collected.

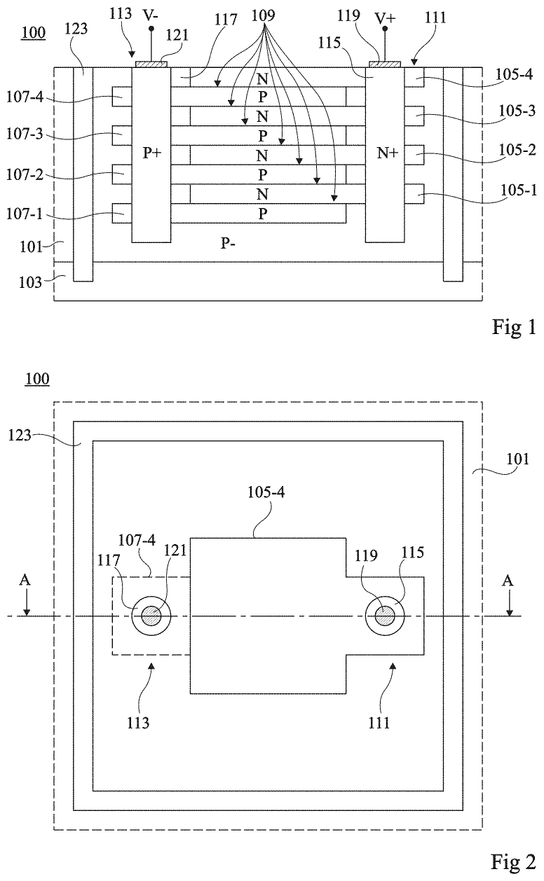

FIGS. 1 and 2 respectively are a cross-section view and a top view, partial and simplified, of an example of a SPAD photodiode 100 according to an embodiment. FIG. 1 is a cross-section view along plane A-A of FIG. 2.

Photodiode 100 comprises a semiconductor substrate 101, for example, made of silicon. In the shown example, substrate 101 is P-type doped (P-). In this example, the lower surface of substrate 101 rests on the upper surface of a support layer 103, for example, an insulating layer, for example, a silicon oxide layer. Layer 103 may itself rest on a support substrate, not shown, for example, made of silicon. As an example, layer 103 corresponds to a buried oxide layer of a structure of semiconductor-on-insulator type (SOI). As a variation, layer 103 is a semiconductor layer, for example, made of the same material as substrate 101, for example having a conductivity type opposite to that of substrate 101.

Photodiode 100 further comprises, in an upper portion of substrate 101, an alternation of vertically stacked semiconductor regions of opposite conductivity types, forming a plurality of stacked horizontal PN junctions, each PN junction defining an avalanche region of the photodiode.

More particularly, in the shown example, photodiode 100 comprises, in an upper portion of substrate 101, an alternation of vertically stacked N-type doped regions 105_i (N) and P-type doped regions 107_j (P), i being an integer ranging from 1 to m and m being an integer greater than or equal to 2 designating the number of N-type regions 105_i of the photodiode, and j being an integer ranging from 1 to n and n being an integer greater than or equal to 2 designating the number of P-type regions 107_j of the photodiode. In the example of FIGS. 1 and 2, n=m, that is, the photodiode comprises as many N-type regions 105_i as P-type regions 107_j. More particularly, in the shown example, m=n=4. Regions 105_i and 107_j are for example made of the same semiconductor material as substrate 101, for example, silicon. Regions 107_j have a P-type doping level greater than that of substrate 101. Preferably, regions 105_i all substantially have the same N-type doping level and regions 107_j all substantially have the same P-type doping level.

In the example of FIGS. 1 and 2, each N-type region 105_i, except for region 105_m, is in contact, by its lower surface, with the P-type region 107_j of rank j=i, and by its upper surface, with the P-type region 107_j of rank j=i+1. In the show example, the upper surface of P-type region 107_1 is in contact, over substantially its entire surface, with substrate 101. As a variation, the lower surface of P-type region 107_1 may be in contact with layer 103. In the shown example, the upper surface of region 105_m is flush with the upper surface of substrate 101. The upper surface of region 105_m is for example in contact with an insulating passivation layer (not shown) of the upper surface of the photodiode, for example, made of silicon oxide. As a variation, the upper surface of N-type region 105_m may be located under the upper surface of substrate 101, in which case the upper surface of region 105_m is in contact with substrate 101.

Thus, the vertical stack of regions 105_i and 107_j comprises (2*m)−1 PN junctions 109 between neighboring regions 105_i and 107_j, that is, 7 PN junctions 109 in the shown example. PN junctions 109 are substantially horizontal (that is, parallel to the main surfaces of substrate 101) and vertically aligned (that is, opposite or vertically in line with one another).

In the example of FIGS. 1 and 2, in a portion 111 of a peripheral region of the photodiode (on the right-hand side of the photodiode in the views of FIGS. 1 and 2), N-type regions 105_i extend laterally beyond P-type regions 107_j. Further, in another portion 113 of a peripheral region of the photodiode (on the left-hand side of the photodiode in the cross-section view of FIG. 1), P-type regions 107_j extend laterally beyond N-type regions 105_i.

Photodiode 100 of FIGS. 1 and 2 further comprises, in peripheral portion 111 of the photodiode, a via 115 filled with an N-type semiconductor material (N+) vertically extending from the upper surface of substrate 101 to N-type semiconductor region 105_1, particularly through N-type regions 105_m to 105_2. Via 115 is in contact with each of the N-type semiconductor regions 105_i of the photodiode. In other words, all the regions 105_i of the photodiode are connected to one another by means of via 115. Via 115 is however not in contact with the P-type semiconductor regions 107_j of the photodiode. More particularly, each P-type region 107_j of the photodiode is separated from via 115 by a portion of substrate 101. Via 115 is for example made of N-type polysilicon, or of N-type doped epitaxial silicon. The doping level of via 115 (N+) is preferably greater than that of regions 105_i.

The photodiode 100 of FIGS. 1 and 2 further comprises, in the peripheral portion 113 of the photodiode, a via 117 filled with a P-type semiconductor material (P+) vertically extending from the upper surface of substrate 101 to P-type semiconductor region 107_1, particularly through P-type regions 107_n to 107_2. Via 117 is in contact with each of the P-type semiconductor regions 107_j of the photodiode. In other words, all the regions 107_j of the photodiode are connected to one another by via 117. Via 117 is however not in contact with N-type semiconductor regions 105_i of the photodiode. More particularly, each N-type region 105_i of the photodiode is separated from via 117 by a portion of substrate 101. Via 117 is for example made of P-type doped polysilicon, or of P-type doped epitaxial silicon. The doping level of via 117 (N+) is preferably greater than that of regions 107_j.

In the shown example, via 115 is in contact, by its upper surface, with a cathode contact metallization 119 of the photodiode, and via 117 is in contact, by its upper surface, with an anode contact metallization 121 of the photodiode.

In the shown example, photodiode 100 is laterally surrounded with a peripheral insulation wall 123 vertically extending from the upper surface of substrate 101 to layer 103. Insulation wall 123 is for example formed of a trench filled with an insulating material, for example, silicon oxide. As a variation, wall 123 comprises a conductive (for example, made of metal) or semiconductor (for example, made of doped polysilicon) central region insulated from substrate 101 by lateral insulating walls (not detailed in FIGS. 1 and 2). Such a variation for example enables to electrically bias layer 103 from the upper surface of the photodiode in the case where layer 103 is made of a semiconductor material.

In operation, regions 105_i, forming cathode regions of the photodiode, are biased to a positive potential V+ by means of via 115, and regions 107_j, forming anode regions of the photodiode, are biased to a negative potential V− by means of via 117, so that the cathode-anode voltage of the photodiode is greater than its avalanche voltage.

The doping levels of regions 105_i and 107_j and the bias voltage of the photodiode are selected so that the electric field in the space charge area of each PN junction 109 is sufficiently intense for the avalanche to be triggered by a single photogenerated charge, for example, greater than 500 kV/cm.

Preferably, the doping level of substrate 101 is selected to be sufficiently low for the electric field in the space charge area of the PN junctions formed between N-type regions 105_i and substrate 101 at the periphery of PN junctions 109 to be sufficiently low for the avalanche not to be triggered by a single photogenerated charge, for example, smaller than 500 kV/cm. This enables to decrease risks of spurious triggering of the avalanche due to edge effects at the periphery of PN junctions 109.

As an example, the reverse breakdown voltage or avalanche voltage of the photodiode is in the range from 10 V to 50 V, and the reverse bias voltage of the photodiode is greater than its breakdown voltage by a value in the range from 0.5 to 10 V. The avalanche voltage of the photodiode particularly depends on the doping levels of regions 105_i and 107_j. As an example, P-type regions 107_j have a doping level in the range from 1*10\hat{ }17 to 1*10\hat{ }19 atoms/cm\hat{ }3 and N-type regions 105_i have a doping level in the range from 1*10\hat{ }17 to 1*10\hat{ }19 atoms/cm\hat{ }3. The doping level of each N-type region 105_i is for example in the order of 1*10\hat{ }17 atoms/cm\hat{ }3 at the level of the junction with the neighboring P-type region(s) 107_j. The doping level of substrate 101 is for example smaller than 5*10\hat{ }16 atoms/cm\hat{ }3 and preferably smaller than 5*10\hat{ }14 atoms/cm\hat{ }3.

The provision of a plurality of vertically stacked avalanche areas enables to efficiently collect the charges photogenerated in the photodiode, whatever the photon absorption depth. In particular, in the photodiode of FIGS. 1 and 2, the mean time which elapses between the photogeneration of a charge in the photodiode and the collection of the charge in an avalanche area of the photodiode is substantially independent from the depth at which the charge has been photogenerated. Further, the sensitivity of the photodiode is improved with respect to a SPAD photodiode with a single PN junction.

To obtain a good detection performance, regions 105_i and 107_j are preferably sized so that the different avalanche areas substantially have the same breakdown voltage whatever the photon detection depth. In other words, regions 105_i and 107_j are preferably such that the different PN junctions 109 of the photodiode have substantially the same avalanche voltage. To achieve this, N-type regions 105_i preferably all have substantially the same dimensions and the same doping level. Further, P-type regions 107_j preferably all have substantially the same dimensions and the same doping level.

As an example, regions 105_i and 107_j each have a thickness in the range from 500nm to 2 μm. In the example of FIGS. 1 and 2, regions 105_i and 107_j have substantially the same thickness. The described embodiments are however not limited to this specific case. The total thickness of the alternated stack of regions 105_i and 107_j is for example in the range from 5 to 25 μm.

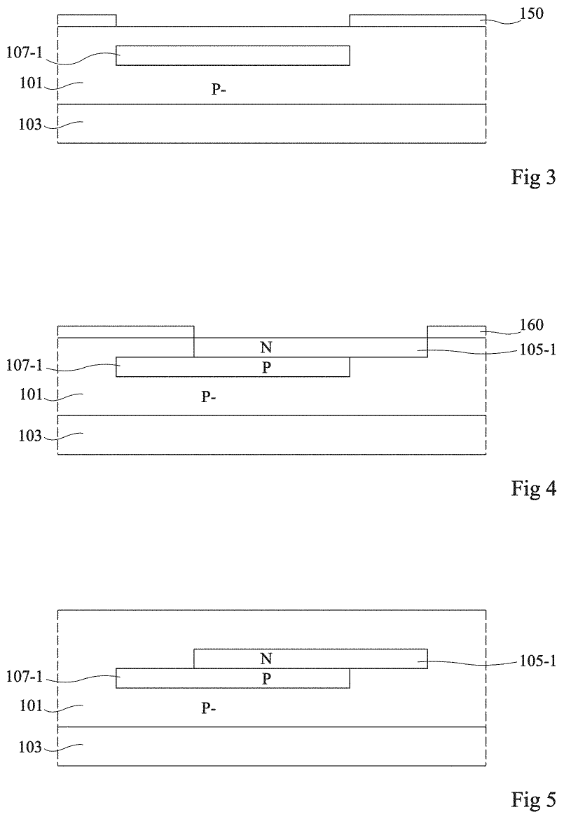

FIGS. 3 to 8 are cross-section views in the same plane as FIG. 1 describing successive steps of an example of a method of manufacturing a SPAD photodiode of the type described in relation with FIGS. 1 and 2. FIGS. 3 to 8 show a single SPAD photodiode. However, in practice, a plurality of identical or similar SPAD photodiodes may be simultaneously formed on a same support substrate, for example, to form an array sensor.

FIG. 3 shows a step of forming, by epitaxy, a first portion of the thickness of substrate 101 on the upper surface of support layer 103 of the photodiode. In this example, the epitaxy is non-local, that is, substrate 101 extends across a substantially uniform thickness over substantially the entire upper surface of the photodiode. The thickness of substrate 101 deposited at this step is for example greater than or equal to the sum of the thicknesses of P-type region 107_1 and of N-type region 105_1 of the photodiode.

FIG. 3 further illustrates a subsequent step of forming P-type region 107_1 of the photodiode, by local implantation of P-type dopant elements in substrate 101 through a masking layer 150 previously formed on the upper surface of substrate 101 and comprising an opening opposite region 107_1. In this example, the implantation power is selected so that region 107_1 is located in depth in substrate 101, that is, so that the upper surface of region 107_1 is located under the upper surface of substrate 101. Once the implantation has been performed, masking layer 150 is removed.

FIG. 4 illustrates a subsequent step of forming N-type region 105_1 of the photodiode, by local implantation of N-type dopant elements in substrate 101 through a masking layer 160 previously formed on the upper surface of substrate 101 and comprising an opening opposite region 105_1. In this example, the implantation power is selected so that region 105_1 extends in depth from the upper surface of substrate 101 to the upper surface of region 107_1. Once the implantation has been performed, masking layer 160 may be removed.

FIG. 5 illustrates a subsequent step of resumption of the epitaxial growth of substrate 101 on the upper surface of the structure obtained at the end of the steps of FIGS. 3 and 4. The additional thickness of substrate 101 deposited at this step is for example substantially equal to the sum of the thicknesses of anode and cathode regions 107_2 and 105_2 of the photodiode. In this example, the epitaxial regrowth is non-local, that is, the additional portion of substrate 101 deposited at this step extends across a substantially uniform thickness over substantially the entire upper surface of the photodiode.

The implantation steps of FIGS. 3 and 4 are then repeated to form P-type region 107_2 and P-type region 105_2 of the photodiode.

The epitaxial regrowth step of FIG. 5, and then the implantation steps of FIGS. 3 and 4, may then be repeated as many times as necessary to form the stack of PN junctions 109 of the photodiode (that is, two additional iterations for the photodiode of FIG. 1).

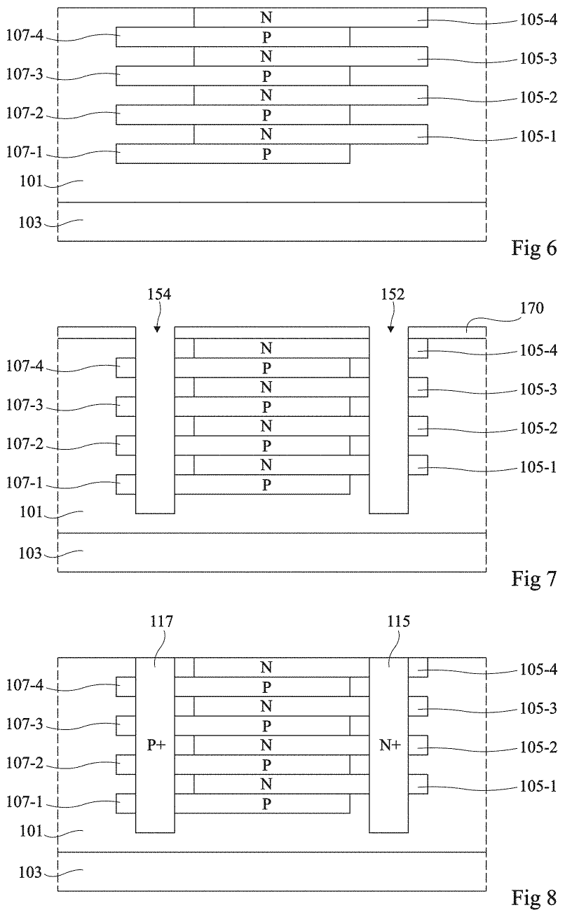

FIG. 6 shows the structure obtained at the end of all the successive steps of epitaxy and then of local implantations of the method. It should be noted that at each epitaxy step of the method, substrate 101 may be doped in situ during the epitaxial growth. The doping level of substrate 101 is preferably substantially the same, for example, in the order of 1*10\hat{ }16 atoms/cm\hat{ }3 at each epitaxy step. Further, the powers and doses of implantation of dopant elements for the forming of regions 105_i and 107_j are preferably substantially identical at each iteration.

At this stage, an anneal of activation of the implanted dopant species may be performed, for example, an anneal at a temperature in the range from 800 to 1,200° C., for example, at a temperature in the order of 1,000° C., for example, for a duration in the range from 1 to 10 seconds. Preferably, a single activation anneal common for all regions 105_i and 107_j of the photodiode is performed at the end of all the epitaxy and implantation steps. In other words, no intermediate activation anneal is performed between two successive steps of implantation of regions 105_i and 107_j of the photodiode, so that all the PN junctions 109 of the photodiode are submitted to the same number of anneals. This enables to obtain substantially identical avalanche diodes for all the PN junctions 109 of the photodiode.

FIG. 7 illustrates a subsequent step of forming of an opening 152 and of an opening 154, respectively in portion 111 and in portion 113 of the photodiode, for the forming of semiconductor vias 115 and 117 of the photodiode. Openings 152 and 154 are formed by etching from the upper surface of the substrate. An etch mask 170 having through openings delimiting, in top view, openings 152 and 154, is previously formed on the upper surface of the photodiode. Opening 152 extends in depth at least all the way to the upper surface of N-type region 105_1 of the photodiode, and opening 154 extends in depth at least all the way to the upper surface of P-type region 107_1 of the photodiode. In the shown example, openings 152 thoroughly crosses N-type region 105_1 and opening 154 thoroughly crosses P-type region 107_1. Openings 152 and 154 for example have substantially the same depth. Masking layer 170 may then be removed.

FIG. 8 illustrates a subsequent step of filling of opening 152 with an N-type semiconductor material to form via 115, and a step of filling of opening 154 with a P-type semiconductor material to form via 117. As an example, openings 152 and 154 are respectively filled with N-type doped polysilicon and with P-type doped polysilicon. As a variation, openings 152 and 154 may be filled by local epitaxy of doped single crystal silicon, respectively of type N for opening 152 and of type P for opening 154. As an example, the N-type doping level of via 115 is in the range from 1*10\hat{ }19 to 1*10\hat{ }20 atoms/cm\hat{ }3, for example in the order of 5*10\hat{ }19 atoms/cm\hat{ }3, and the P-type doping level of via 117 is in the range from 1*10\hat{ }19 to 1*10\hat{ }20 atoms/cm\hat{ }3, for example in the order of 5*10\hat{ }19 atoms/cm\hat{ }3. A fast anneal of activation of the dopant species of vias 115 and 117 may be provided at the end of the step of filling of openings 152 and 154, for example, an anneal at a temperature in the range from 800 to 1,200° C., for example, at a temperature in the order of 1,000° C., for example, for a duration in the range from 1 to 15 seconds.

Steps (not detailed) of forming of contact metallizations 119 and 121 on the upper surfaces of vias 115 and 117 and of forming of peripheral insulating walls 123 may then be implemented to obtain the structure of FIGS. 1 and 2.

In the method described in relation with FIGS. 3 to 8, two successive implantation steps are provided after each epitaxy step, to respectively form a P-type region 107_j and the immediately upper N-type region 105_i. Four successive epitaxy steps are thus provided to form photodiode 100 of FIG. 1. As a variation, a specific implantation step may be provided before each P- or N-type implantation step, that is, eight epitaxy steps to form the photodiode of FIG. 1.

It should be noted that before each epitaxy, a cleaning of the upper surface of the substrate may be provided, for example, by means of a solution based on hydrofluoric acid, to improve the quality of the epitaxy.

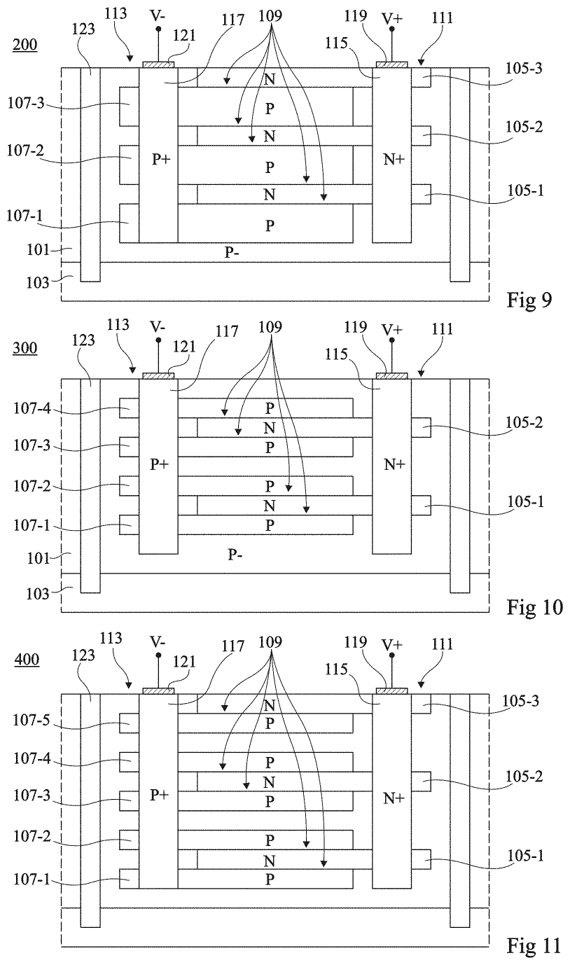

FIG. 9 is a partial simplified cross-section view of another example of a SPAD photodiode 200 according to an embodiment.

The photodiode 200 of FIG. 9 differs from the photodiode 100 of FIGS. 1 and 2 mainly in that, in the example of FIG. 9, the P-type regions 107_j of the photodiode have a thickness greater than that of N-type regions 105_i, for example, a thickness in the range from 1.5 times to 5 times the thickness of N-type regions 105_i.

An advantage of such a configuration is that it enables to increase the proportion of photons absorbed in P-type regions 107_j over the photons absorbed in N-type regions 105_i. This enables to improve the sensitivity of the photodiode. Indeed, in the case of an absorption of a photon in an N-type region, the electron of the photogenerated electron-hole pair is discharged by means of via 115, and the remaining photogenerated charge capable of triggering the avalanche is a hole, while in case of an absorption of a photon in a P-type region, the hole of the photogenerated electron-hole pair is discharged by mean of via 117, and the remaining photogenerated charge capable of triggering the avalanche is an electron. The mobility of electrons being greater than that of holes, the avalanche is more easily detected by a photogenerated electron than by a photogenerated hole. In other words, the avalanche is more easily detected by a photon absorbed in a P-type region 107_j than by a photon absorbed in an N-type region 105_i.

In the example of FIG. 9, photodiode 200 comprises m=3 N-type regions 105_i and n=3 P-type regions 107_j, that is, 5 PN junctions 109.

FIG. 10 is a partial simplified cross-section view of another example of a SPAD photodiode 300 according to an embodiment.

The photodiode 300 of FIG. 10 differs from the photodiode 100 of FIGS. 1 and 2 mainly in that, in photodiode 300, each N-type region 105_i is in contact with two P-type regions 107_j, each P-type region 107_j being in contact with a single N-type region 105_i.

More particularly, in the example of FIG. 10, photodiode 300 comprises m N-type regions 105_i, and n=2*m P-type doped regions 107_j. In the example shown in FIG. 10, number m of N-type regions 105_i is equal to 2.

Each N-type region 105_i is in contact, by its lower surface, with the P-type region 107_j of rank j=(2*i)−1 and, by its upper surface, with the P-type region of rank j=2*i. Thus, photodiode 300 comprises 2*m PN junctions 109 between neighboring regions 105_i and 107_j, that is, 4 PN junctions 109 in the shown example.

In the example of FIG. 10, each N-type region 105_i, except for region 105_m, is separated from N-type region 105_i+1 by a portion of substrate 101 extending between the upper surface of the P-type region 107_j of rank j=2*i (that is, the region 107_j in contact with the upper surface of region 105_i) and the lower surface of the P-type region 107_j of rank j=(2*i)+1 (that is, the region 107_j in contact with the lower surface of region 105_i+1)

In the shown example, the thicknesses of regions 105_i and 107_j are substantially identical. As a variation, regions 105_i and 107_j may have different thicknesses.

FIG. 11 is a partial simplified cross-section view of another example of a SPAD photodiode 400 according to an embodiment.

The photodiode 400 of FIG. 11 differs from the photodiode 300 of FIG. 10 mainly in that, in the example of FIG. 11, the N-type region 105_i closest to the upper surface of the photodiode, that is, region 105_m, is in contact with a P-type region P 107_j only by its lower surface. In other words, in the present example, the photodiode comprises m N-type regions 105i and n=(2*m)−1 P-type regions 107_j for a total of (2*m)−1 PN junctions 109 between neighboring regions 105_i and 107_j. In the shown example, the photodiode comprises m=3 N-type regions 105_i, that is, a total of 5 PN junctions 109.

Specific embodiments have been described. Various alterations, modifications, and improvements will occur to those skilled in the art. In particular, the described embodiments are not limited to the numerical examples of dimensions and of doping levels mentioned in the description.

Further, the above-described advantages can be obtained by inverting all the conductivity types with respect to the examples described in relation with FIGS. 1 to 11.

Further, the described embodiments are not limited to the example of a manufacturing method described in relation with FIGS. 3 to 8. As a variation, rather than forming regions 105_i and 107_j of the photodiode by successive steps of implantation of N-type and of P-type dopant elements, regions 105_i and 107_j may be formed by successive steps of N-type and P-type local epitaxy or selective epitaxy.

What is claimed is:

1. A SPAD-type photodiode comprising, in an upper portion of a semiconductor substrate of a first conductivity type, an alternation of vertically stacked regions of the first conductivity type and regions of a second conductivity type, the regions of the first conductivity type being in contact with a same first semiconductor via of the first conductivity type and the regions of the second conductivity type being in contact with a same second semiconductor via of the second conductivity type, wherein, in a first portion of a peripheral region of the photodiode, the regions of the first conductivity type extend laterally beyond the regions of the second conductivity type, and, in a second portion of the peripheral region of the photodiode, the regions of the second conductivity type extend laterally beyond the regions of the first conductivity type, the first semiconductor via being arranged in the first portion of the peripheral region of the photodiode so that the first semiconductor via is not in contact with the regions of the second conductivity type, and the second semiconductor via being arranged in the second portion of the peripheral region of the photodiode so that the second semiconductor via is not in contact with the regions of the first conductivity type.

2. The photodiode of claim 1, wherein said alternation of regions of the first conductivity type and of regions of the second conductivity type forms a vertical stack of a plurality of PN junctions each defining an avalanche region of the photodiode.

3. The photodiode of claim 2, wherein said PN junctions all substantially have the same avalanche voltage.

4. The photodiode of claim 1, wherein the regions of the first conductivity type have a doping level greater than that of the substrate.

5. The photodiode of claim 1, wherein, except for the end regions of said alternation, each region of the first conductivity type is in contact, by its lower surface, with one of the regions of the second conductivity type and, by its upper surface, with another one of the regions of the second conductivity type, and each region of the second conductivity type is in contact, by its lower surface, with one of the regions of the first conductivity type and, by its upper surface, with another one of the regions of the first conductivity type.

6. The photodiode of claim 5, wherein the regions of the first conductivity type and the regions of the second conductivity type have substantially the same thickness.

7. The photodiode of claim 5, wherein the regions of the first conductivity type have a thickness greater than the thickness of the regions of the second conductivity type.

8. The photodiode of claim 1, wherein each region of the first conductivity type is in contact with a single region of the second conductivity type.

9. The photodiode of claim 8, wherein each region of the second conductivity type is in contact, by its lower surface, with one of the regions of the first conductivity type and, by its upper surface, with another one of the regions of the first conductivity type.

10. The photodiode of claim 8, wherein:
at least one of the regions of the second conductivity type is in contact, by its lower surface, with one of the regions of the first conductivity type and, by its upper surface, with another one of the regions of the first conductivity type; and
at least another one of the regions of the second conductivity type is in contact with a single one of the regions of the first conductivity type.

11. The photodiode of claim 1, wherein the first and second conductivity types respectively are type P and type N.

12. A method of manufacturing the SPAD-type photodiode of claim 1, wherein the substrate is formed by a sequence of successive epitaxy steps.

13. The method of claim 12, wherein any two successive steps of the sequence of successive epitaxy steps are separated by at least one step of local implantation of dopant elements for the forming of at least one of the regions of the first or second conductivity type.

14. The method of claim 13, comprising no anneal of activation of the dopant elements between two successive steps of the sequence of epitaxy steps, the method comprising a single anneal of activation of the dopant elements common to all the regions of the first and second conductivity types at the end of the sequence of successive epitaxy steps.
